(19) United States
(12) Patent Application Publication
(10) Pub. No.: US 2015/0370731 A1
(43) Pub. Date: Dec. 24, 2015

(54) MEMORY SYSTEM AND METHOD FOR OPERATING THE SAME

(71) Applicant: SK hynix Inc., Gyeonggi-do (KR)

(72) Inventors: Hyun-Ju YOON, Gyeonggi-do (KR); Ji-Hoon CHOI, Gyeonggi-do (KR)

(21) Appl. No.: 14/555,430

(22) Filed: Nov. 26, 2014

(30) Foreign Application Priority Data
Jun. 19, 2014 (KR) 10-2014-0074955

(51) Int. Cl. G06F 13/16; G11C 7/10

(52) U.S. Cl. CPC G06F 13/1626; G11C 7/1072

(57) ABSTRACT

A memory system includes a common data bus, a common control bus, memory devices suitable for sharing the common data bus and the common control bus, wherein the memory devices each have different latencies for recognizing control signals of the common control bus, and a controller suitable for controlling the memory devices through the common data bus and the common control bus.

### CROSS-REFERENCE TO RELATED APPLICATIONS

The present application claims priority of Korean Patent Application No. 10-2014-0074955, filed on Jun. 19, 2014, which is incorporated herein by reference in its entirety.

### BACKGROUND

1. Field

Various embodiments of the present invention relate to a semiconductor design technology, and more particularly, to a memory system.

2. Description of the Related Art

In general, a controller is coupled with memory devices to be controlled in a one o-many relationship. That is, one controller is coupled with multiple memory devices.

FIGS. 1A and 1B are block diagrams illustrating a conventional bus connection between a controller and memory devices.

As shown in FIG. 1A, a memory system includes a controller 100, a memory device 110_0 and a memory device 110_1. When a control bus CMD/ADDR_BUS0 transmits commands and addresses between the controller 100 and the memory device, 110_0, a data bus DATA_BUS0, a control bus CMD/ADDR_BUS1, which transmits the commands and the addresses between the controller 100 and the memory device 110_1, and a data bus DATA_BUS1 are separated from each other, the controller 100 may direct the memory devices 110_0 and 110_1 to perform completely separate operations. For example, the memory device 110_1 may perform a write operation while the memory device 110_0 performs a read operation.

As shown in FIG. 1B, when a control bus CMD/ADDR_BUS and a data bus DATA_BUS are shared with the memory devices 110_0 and 110_1, lines are formed to transmit at least selection signals CS0 and CS1, which are a kind of command signals, for distinguishing the memory device 110_0 from the memory device 110_1. In other words, the lines for transmitting selection signals CS0 and CS1 may not be shared with the memory devices 110_0 and 110_1 and have to be separately formed. In this case, a memory device selected based on the selection signals CS0 and CS1 among the memory devices 110_0 and 110_1 may perform an operation directed by the control bus CMD/ADDR_BUS and exchange the signals with the controller 100 through the data bus DATA_BUS. Although the selection signals CS0 and CS1 belong to the command signals, the selection signals CS0 and CS1 are separately assigned to the memory devices 110_{—}0 and 110_1 differently from other command signals transmitted to the control bus CMD/ADDR_BUS.

As the number of memory devices coupled with a controller increases, the number of required lines, that is, bus lines, also increases. This may increase the production cost and difficulty in system design.

### SUMMARY

Various embodiments of the present invention are directed to a memory system that may reduce the number of lines between a controller and memory devices, and allow the controller to individually access the memory devices.

In accordance with an embodiment of the present invention, memory system includes: a common data bus; a common control bus; memory devices suitable for sharing the common data bus and the common control bus, wherein the memory devices each have different latencies for recognizing control signals of the common control bus; and a controller suitable for controlling the memory devices through the common data bus and the common control bus.

In accordance with an embodiment of the present invention, a memory system includes: a common control bus including a plurality of control signal transmission lines; a common data bus including first to N^{th} data lines; and memory devices suitable for sharing the common data bus and the common control bus, wherein each of the memory devices includes first to N^{th} data pads, and has different corresponding connections between the first to N^{th} data lines and the first to N^{th} data pads.

In accordance with an embodiment of the present invention, a method for operating a memory system having a controller and first and second memory devices includes: setting, by the controller, the first memory device to have a first latency for a common control bus; setting, by the controller, the second memory device to have a second latency, which is different from the first latency, for the common control bus; transmitting, by the controller, control signals with the first latency to the common control bus when the controller accesses the first memory device; and transmitting, by the controller, control signals with the second latency to the common control bus when the controller accesses the second memory device.

### BRIEF DESCRIPTION OF THE DRAWINGS

FIGS. 1A and 1B are block diagrams illustrating a conventional bus connection between a controller and memory devices.

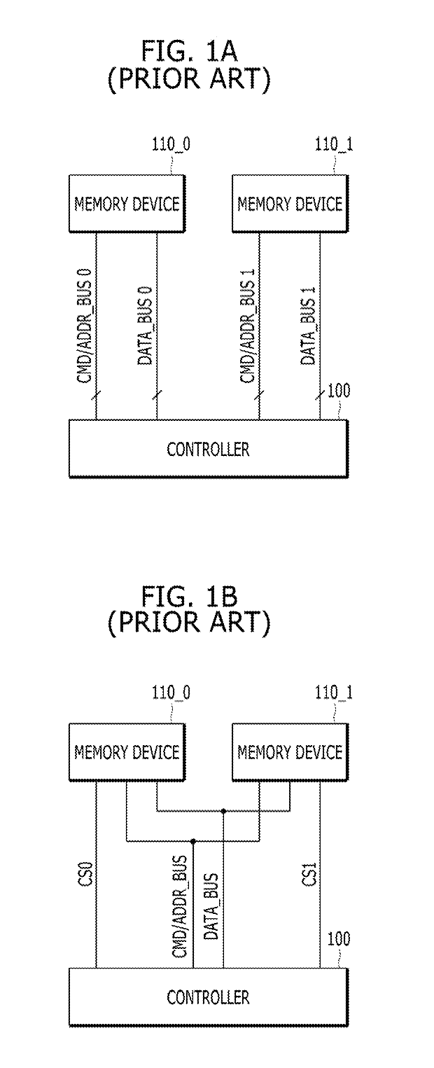

FIG. 2 is a timing diagram for describing an operation of a mode register set (MRS) in a per DRAM addressability (PDA) mode of a memory device.

FIG. 3 is a timing diagram for describing a command address latency (CAL) of a memory device.

FIG. 4 is a block diagram illustrating a memory system in accordance with an embodiment of the present invention.

FIG. 5 is a flowchart for describing an operation of the memory system shown in FIG. 4.

FIG. 6 is a timing diagram for describing operations shown in FIG. 5.

FIGS. 7A and 7B are timing diagrams for describing operations shown in FIG. 5.

FIG. 8 is a block diagram illustrating a memory system in accordance with an embodiment of the present invention.

### DETAILED DESCRIPTION

Exemplary embodiments of the present invention are described below in snore detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The drawings are not necessarily to scale and in some instances proportions may have been exaggerated to clearly illustrate features of the embodiments. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

A per DRAM address ability (PDA) mode and a command address latency (CAL) are described below.

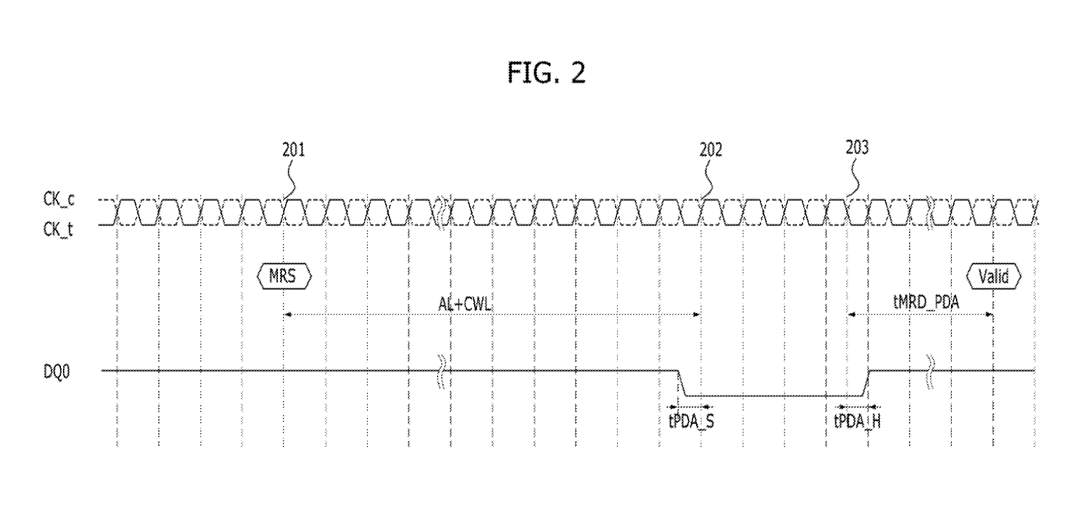

FIG. 2 is a timing diagram for describing an operation of a mode register set (MRS) in a PDA mode of a memory device.

The PDA mode may support each memory device to independently perform a mode register set operation. When the PDA mode is set, the validity of all mode register set commands may be determined based on a signal level of a 0^{th} data pad DQ0. After a write latency WL passes from a moment when one mode register set command is applied, the applied mode register set command is determined to be valid when the signal level of the 0^{th} data pad DQ0 is set to “0”, and the applied mode register set command may be ignored since it is determined to be invalid when the signal level of the 0^{th} data pad DQ0 is set to “1”. Here, the write latency WL may correspond to a value obtained by adding an additive latency AL and a CAS write latency CWL (WL=AL+CWL).

Referring to FIG. 2, a mode register set command MRS is applied to the memory device at a moment 201. The signal level of the 0^{th} data pad DQ0 transitions to “0” during a predetermined section at a moment 202 when a time corresponding to the write latency WL passes from the moment 201. Therefore, the mode register set command MRS applied to the memory device at the moment 201 is determined to be valid, and a set operation of the memory device starts to be performed based on an address (not shown) inputted along with the mode register set command MRS while a mode register set command cycle time tMRD_PDA passes from a moment 203. For reference, tPDA_S denotes a setup time for a PDA mode flag, and tPDA_H denotes a hold time for the PDA mode flag.

When the signal level of the 0^{th} data pad DQ0 is “1” at the moment 202, the mode register set command MRS applied to the memory device at the moment 201 is ignored since it is determined to be invalid. That is, the set operation of the memory device is not performed.

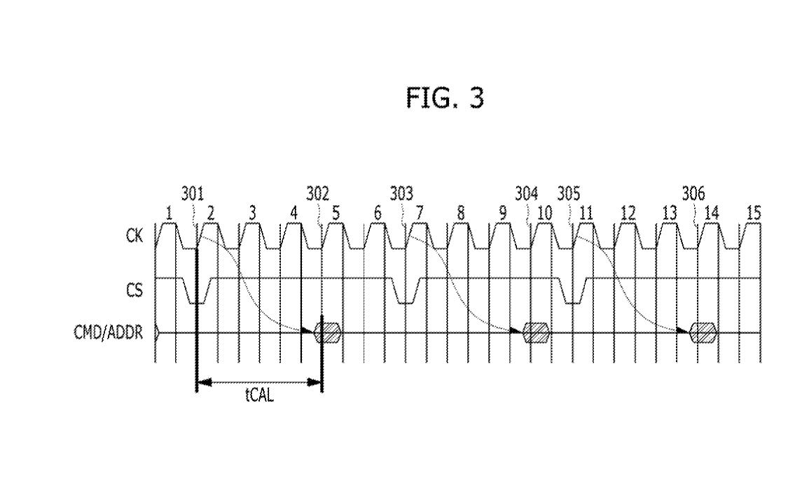

FIG. 3 is a timing diagram for describing a CAL of a memory device.

The CAL indicates a timing difference between a chip selection signal CS, which serves as a reference signal, and the other signals among control signals transmitted to a control bus CMD/ADDR_BUS. When the CAL is set, the memory device recognizes control signals to be valid which are inputted after a time tCAL, corresponding to the CAL passes from an active moment of the chip selection signal CS. The CAL may be set based on the mode register set command MRS.

FIG. 3 shows an operation performed when the CAL is set to 3tCK, Commands CMD, which are signals other than the chip selection signal CS among command signals, and addresses ADDR are applied to the memory device at a moment 302 when 3 clock cycles pass from a moment 301 and the chip selection signal CS is activated to a logic low level. The memory device may recognize the commands CMD and the addresses ADDR applied at the moment 302 to be valid. If the commands CMD and the addresses ADDR are applied to the memory device before 3tCK passes from the moment 301 when the chip selection signal CS is activated, the memory device does not recognize the applied commands CMD and the addresses ADDR to be valid.

Since the commands CMD and the addresses ADDR are applied to the memory device at moments 304 and 306 when times corresponding to the CAL pass, even after moments 303 and 305 to when the chip selection signal CS is activated, the commands CMD and the addresses ADDR applied at the moments 304 and 306 may also be recognized as valid by the memory device.

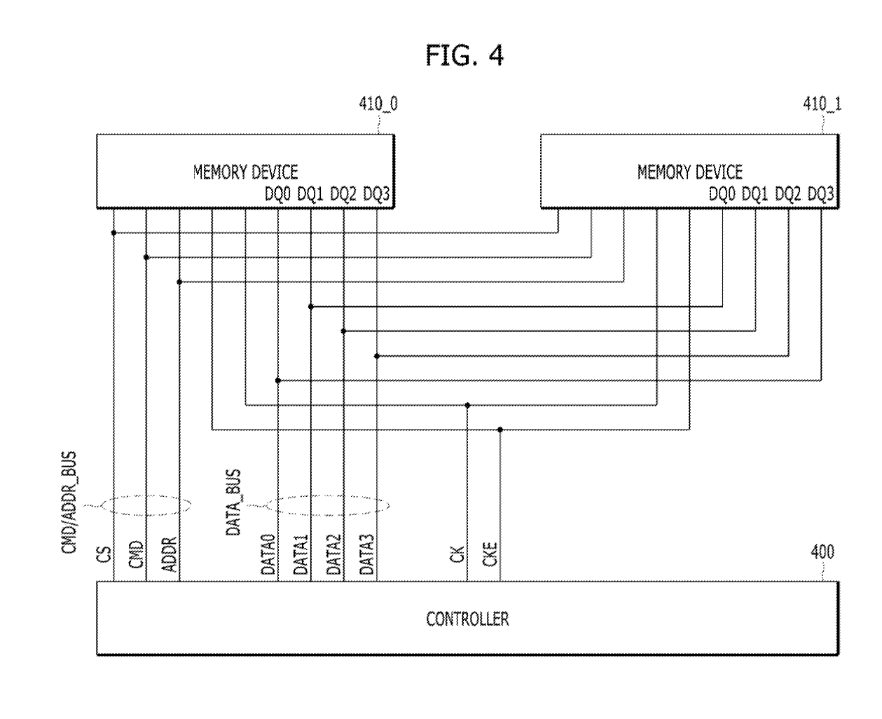

FIG. 4 is a block diagram illustrating a memory system in accordance with an embodiment of the present invention.

Referring to FIG. 4, the memory system may include a controller 400, a first memory device 410_0 a second memory device 410_1 a control bus CMD/ADDR_BUS, and a data bus DATA_BUS. The memory system may further include a line for transmitting a clock CK and a line for transmitting a clock enable signal CINE directing a moment when the memory devices 410_0 and 410_1 have to operate in synchronization with the clock CK.

Control signals may be transmitted from the controller 400 to the memory devices 410_0 and 410_1 through the control bus CMD/ADDR_BUS. The control signals may include commands CMD and addresses ADDR. The commands may include a plurality of signals. For example, the commands may include an active signal ACT, a row address strobe signal RAS, a column address strobe signal CAS and a chip selection signal CS. Although the chip selection signal CS is included in the commands CMD, it is separately illustrated in the drawing to show that the memory devices 410_0 and 410_1 share the same chip selection signal CS with each other. The addresses ADDR may include a plurality of signals. For example, the addresses ADDR may include a multi-bit bank group address, a multi-bit bank address and a multi-bit normal address.

The data bus DATA_BUS may transmit multi-bit data DATA0 to DATA3 between the controller 400 and the memory devices 410_0 and 410_1. Each of the memory devices 410_0 and 410_1 includes data pads DQ0 to DQ3 for being coupled with data lines DATA0 to DATA3 of the data bus DATA_BUS. The data lines DATA0 and DATA1 having different numbers 0 and 1 may be coupled with a predetermined data pad DQ0 among the data pads DQ0 to DQ3 for the memory devices 410_0 and 410_1. That is, each of the memory devices 410_0 and 410_1 has different corresponding connections between the data lines data lines DATA0 and DATA1 and the data pads DQ0 to DQ3, The predetermined data pad DQ0 may be a data pad which is used for setting a latency for recognizing the control signals of the control bus CMD/ADDR_BUS.

The clock CK may be transmitted from the controller 400 to the memory devices 410_0 and 410_1 for the synchronized operations of the memory devices. The clock CK may be transmitted in a differential way including a clock and a complementary clock. The clock enable signal CKE may notify a moment when the memory devices 410_0 and 410_1 have to operate in synchronization with the clock CK.

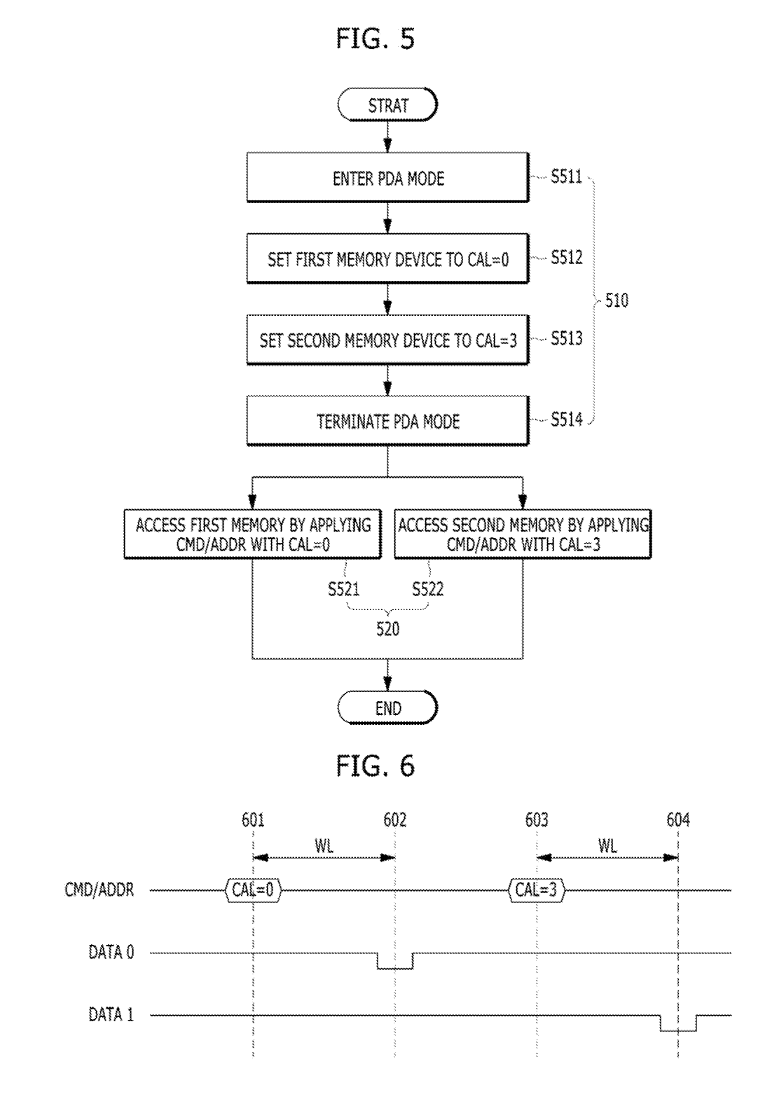

The controller 400 may control the memory devices 410_0 and 410_1 through the control bus CMD/ADDR_BUS and exchange the data with the memory devices 410_0 and 410_1 through the data bus DATA_BUS. The controller 400 may be included in a processor such as a central processing unit (CPU), graphic processing unit (GPU) and application processor (AP) and exist on a memory module such as dual n-line memory module (DIMM). Also, the controller 400 may be formed in various shapes such as existing on a separate chip in a system such as, a computing device, a mobile phone, etc., including memory devices. The controller 400 may set the memory devices 410_0 and 410_1 to have different values of the latencies by recognizing the signals of the control bus CMD/ADDR_BUS and access a desired memory device among the memory devices 410_0 and 410_1. A detailed description is described with reference to FIGS. 5 to 7.

The first memory device 410.0 and the second memory device 410_1 may share the control bus CMD/ADDR_BUS and the data bus DATA_BUS with each other, that is, the control bus CMD/ADDR_BUS and the data bus DATA_BUS are common. The first memory device 410_0 and the second memory device 410_1 may share the chip selection signal Cs with each other. The first memory device 410_0 and the second memory device 410_1 may set the latency differently for the control signals transmitted to the control bus CMD/ADDR_BUS. The latency may indicate a timing difference between the reference signal CS, which is a reference of the latency, and the other signals CMD and ADDR among the signals of the control bus CMD/ADDR_BUS. The first memory device 410_0 and the second memory device 410_1 may be individually accessed by the controller 400 when the latency for the signals CMD/ADDR of the control bus CMD/ADDR_BUS is differently set from each other. A detailed description is described with reference to FIGS. 5 to 7.

As shown in FIG. 4, any signal transmission line for distinguishing the memory devices from each other is not separately assigned to the first memory device 410_0 and the second memory device 410_1. However, the controller 400 may separately access the first memory device 410_0 and the second memory device 410_1, as described below.

FIG. 5 is a flowchart for describing an operation of the memory system shown in FIG. 4.

Referring to FIG. 5, the operation of the memory system may be divided into an operation 510 for setting the latency differently for the control signals transmitted to the control bus CMD/ADDR_BUS of the first memory device 410_0 and the second memory device 410_1, and an operation 520 for separately accessing the first memory device 410_0 and the second memory device 410_1.

The controller 400 may control the first memory device 410_0 and the second memory device 410_1 to enter a PDA mode in step S511. This may be realized by applying the commands CMD to a combination corresponding to the MRS and applying the addresses ADDR to a combination corresponding to the entry to the PDA mode.

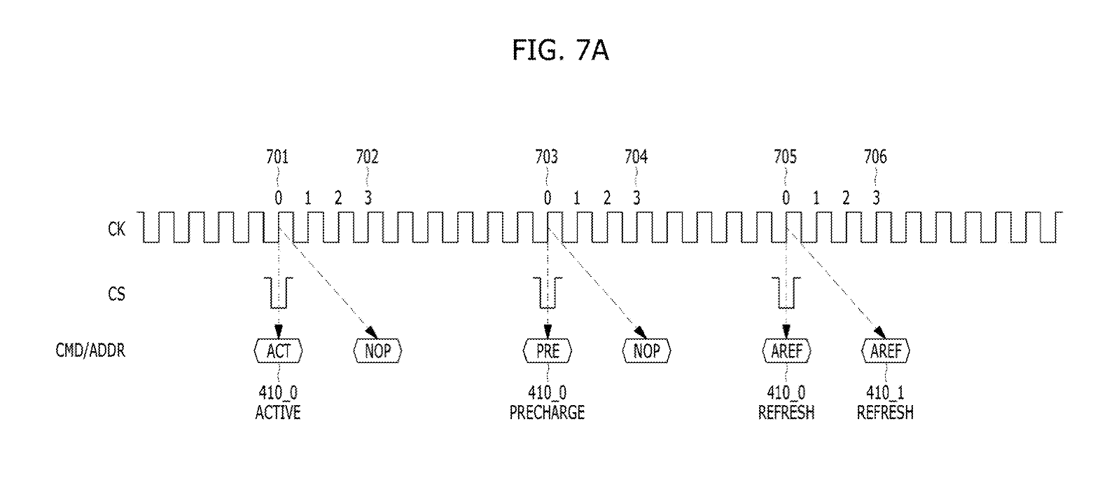

After entry to the PDA mode, a latency, that is, a CAL, corresponding to the control bus CMD/ADDR_BUS of the first memory device 410_0 may be set to “0” in step S512. This may be realized by applying the commands CMD to a combination corresponding to the MRS, applying the addresses ADDR to a combination corresponding to the setting of the CAL to “0”, and applying a signal of a 0^{th} data line DATA0 corresponding to a 0^{th} data pad DQ0 of the first memory device 410_0 in a logic “0” level after a write latency WL, that is, AL+CWL, passes from a moment when the commands CMD are applied. Referring to FIG. 6, the commands/addresses CMD/ADDR for setting the CAL to “0” are applied at a moment 601, and the data line DATA0 has a logic “0” level at a moment 602 when a time corresponding to the write latency WL passes from the moment 601. Since the data line DATA1 has a logic “1” level at the moment 602, the second memory device 410_1 ignores the commands applied at the moment 601.

A latency, that is, a CAL, corresponding to the control bus CMD/ADDR_BUS of the second memory device 410_1 may be set to “3” in step S513. This may be realized by applying the commands CMD to a combination corresponding to the MRS, applying the addresses ADDR to a combination corresponding to the setting of the CAL to “3”, and applying a signal of a first data line DATA1 corresponding to a 0^{th} data pad DQ0 of the second memory device 410_1 in a logic “0” level after a write latency WL, that is, AL+CWL, passes from a moment when the commands CMD are applied. Referring to FIG. 6, the commands/addresses CMD/ADDR for setting the CAL to “3” are applied at a moment 603, and the data line DATA1 has a logic “0” level at a moment 604 when a time corresponding to the write latency WL passes from the moment 603. Since the data line DATA0 has a logic “1” level at the moment 604, the first memory device 410_0 ignores the commands applied at the moment 603. When the latencies of the memory devices 410_0 and 410_1 are set, the PDA mode may be terminated in step S514.

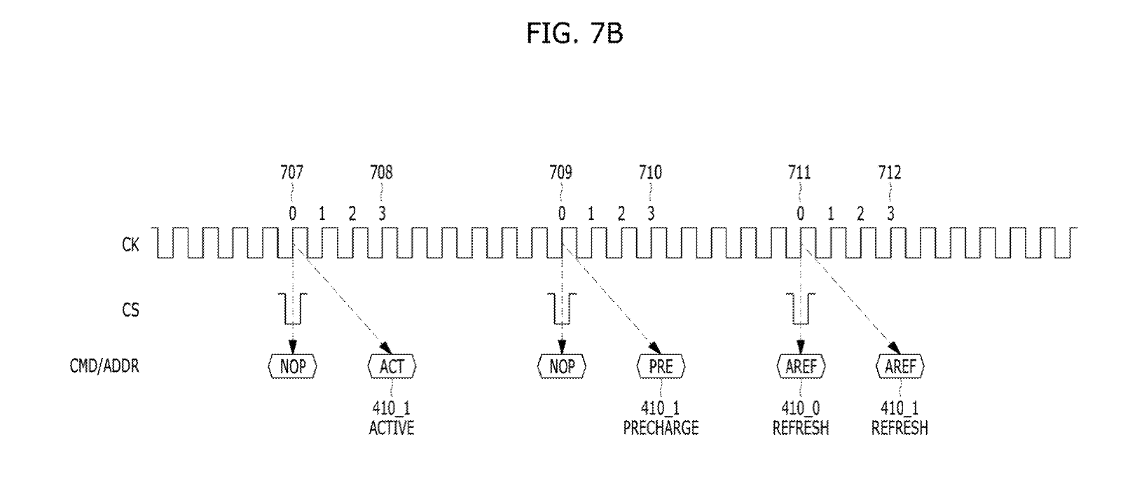

Since the CALs of the first memory device 410_0 and the second memory device 410_1 are set differently from each other, the controller 400 may access the first memory device 410_0 by applying the commands/addresses CMD/ADDR at an active moment of the chip selection signal CS in step S521, or access the second memory device 410_1 by applying the commands/addresses CMD/ADDR after 3 clock cycles pass from the active moment of the chip selection signal CS in step S522. FIGS. 7A and 7B are timing diagrams for describing the operations shown in the steps 521 and 522. Referring to FIGS. 7A and 7B, the commands applied at the same moments 701, 703, 705, 707, 709 and 711 as the active moment of the chip selection signal CS are recognized by the first memory device 410_0 and operate the first memory device 410_0, and the commands applied at moments 702, 704, 706, 708, 710 and 712 after 3 clock cycles pass from the active moment of the chip selection signal CS are recognized by the second memory device 410_1 and operate the second memory device 410_1. Here, “NOP” indicates a non-operation state where no operation is commanded. One memory device, that is, the first memory device or the second memory device, may be accessed as in the operations at the moments 701, 702, 703, 704, 707, 708, 709 and 710. In addition, it may be possible to access both of the first memory device 410_0 and the second memory device 410_1 when the valid commands CMD are applied even at the active moment of the chip selection signal CS, and the valid commands CMD are applied after the 3 clock cycles pass from the active moment of the chip selection signal CS, such as the operations at the moments 705, 706, 711 and 712.

In accordance with the embodiments of the present invention described with reference to FIGS. 4 to 7, the memory devices 410_0 and 410_1 share the control bus CMD/ADDR_BUS and the data bus DATA_BUS with each other but have different latencies for the control bus CMD/ADDR_BUS. The controller 400 may access a memory device desired to be accessed among the memory devices 410_0 and 410_1, based on a change of the latencies of the signals applied to the control bus CMD/ADDR_BUS. Therefore, no line needs to be added to individually control the memory devices 410_3 and 410_1.

Although it is described in the embodiments that the memory devices 410_0 and 410_1 are set by the controller 400 to have different latencies for the control bus CMD/ADDR_BUS, the inventive concept is not limited to this, and the memory devices 410_0 and 410_1 may be programmed to permanently have different latencies in accordance with this invention. For example, the latencies for the control bus CMD/ADDR_BUS may be fixed when the memory devices 410_0 and 410_1 are fabricated, and the latencies for the control bus CMD/ADDR_BUS of the memory devices 410_3 and 410_1 may be fixed through a permanent setting, such as, a setting using a fuse circuit, after the memory devices 410_0 and 410_1 are fabricated.

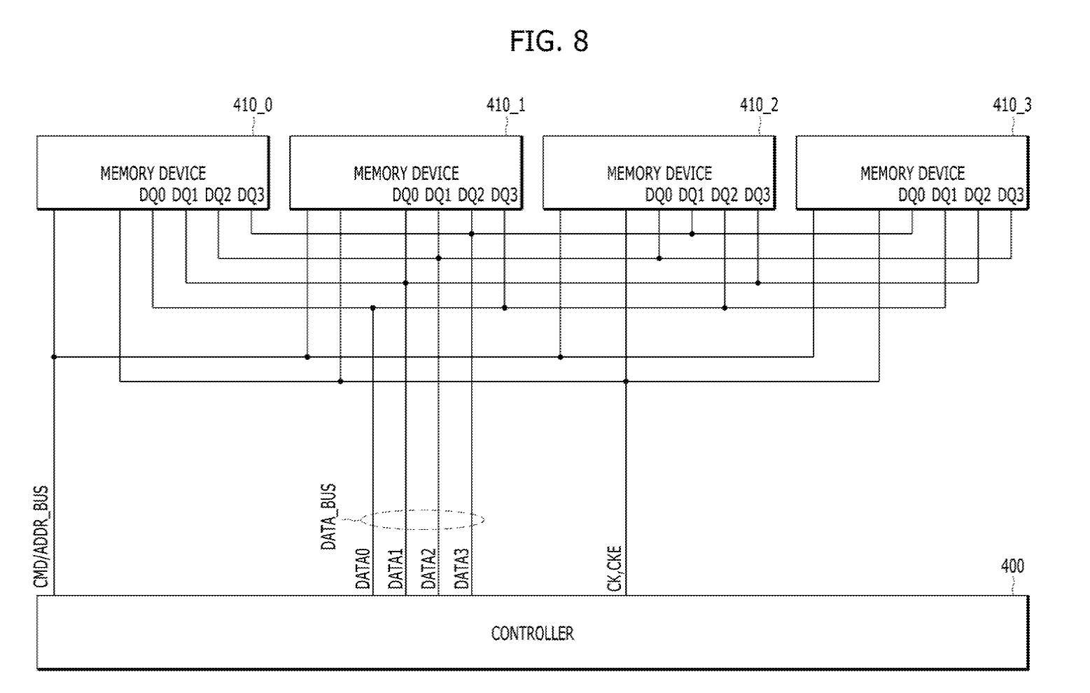

FIG. 8 is a block diagram illustrating a memory system in accordance with an embodiment of the present invention. FIG. 8 illustrates a simplified control bus CMD/ADDR_BUS, clock CK and clock enable signal CKE transmission line having the same coupling structure as shown in FIG. 4.

In the embodiment of FIG. 8, memory devices 4102 and 410_3 are added as compared with the embodiment of FIG. 4. The added memory devices 410_2 and 410_3 may also share the control bus CMD/ADDR_BUS and the data bus DATA_BUS with each other. Different data Ones DATA0 to DATA3 for the memory devices 410_0 to 410_3 may be coupled with a predetermined data pad DQ0 for setting a latency.

In the memory system shown in FIG. 8 similar to the memory system shown in FIG. 4, the memory devices 410_0 to 410_3 may be set to have different latencies for the control bus CMD/ADDR_BUS. For example, the semiconductor device 410_0 may have a latency of “0”, and the semiconductor device 410_1 may have a latency of “1”, to and the semiconductor device 410_2 may have a latency of “2”, and the semiconductor device 410_3 may have a latency of “3”. A controller 400 may access a desired memory device among the memory devices 410_0 to 410_3 under the control of the latency of the control bus CMD/ADDR_BUS.

In accordance with the embodiments of the present invention, the number of lines between a controller and memory devices may be reduced, and simultaneously the controller may individually access the memory devices.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the scope of the present invention as defined by the following claims.

What is claimed is:

1. A memory system, comprising:
a common data bus;
a common control bus;
memory devices suitable for sharing the common data bus and the common control bus, wherein the memory devices each have different latencies for recognizing control signals of the common control bus, and
a controller suitable for controlling the memory devices through the common data bus and the common control bus.

2. The memory system of claim 1, wherein the controller transmits the control signals to the common control bus by applying the different latencies to the respective memory device.

3. The memory system of claim 2, wherein each of the latencies is a timing difference between a reference signal and the other signals among the control signals.

4. The memory system of claim 3, wherein the reference signal includes a chip selection signal, and the other signals include command signals and address signals.

5. The memory system of claim 4, wherein the latency is command address latency.

6. A memory system, comprising:
a common control bus including a plurality of control signal transmission lines;
a common data bus including first to N^{th} data lines; and
memory devices suitable for sharing the common data bus and the common control bus,
wherein each of the memory devices includes first to N^{th} data pads, and has different corresponding connections between the first to N^{th} data lines and the first to N^{th} data pads.

7. The memory system of claim 6, wherein data lines having different numbers among the first to N^{th} data lines are coupled with a K^{th} data pad of the memory devices, where K is an integer ranging from 1 to N.

8. The memory system of claim 7, further comprising:
a controller suitable for controlling the memory devices through the common control bus and the common data bus.

9. The memory system of claim 8, wherein the memory devices are set to have different latencies for recognizing the control signals of the common control bus.

10. The memory system of claim 9, wherein the controller sets the different latencies to the respective memory device by using the common control bus and the data lines coupled with the K^{th} data pads.

11. The memory system of claim 9, wherein the controller transmits the control signals to the common control bus by applying the different latencies to the respective memory device.

12. The memory system of claim 9, wherein each of the latencies is a timing difference between a reference signal and the other signals among the control signals.

13. The memory system of claim 12, wherein the reference signal includes a chip selection signal, and the other signals include command signals and address signals.

14. A method for operating a memory system including a controller and first and second memory devices, the method comprising:
setting, by the controller, the first memory device to have a first latency for a common control bus;
setting, by the controller, the second memory device to have a second latency, which is different from the first latency, for the common control bus;
transmitting, by the controller, control signals with the first latency to the common control bus when the controller accesses the first memory device; and
transmitting, by the controller, control signals with the second latency to the common control bus when the controller accesses the second memory device.

15. The method of claim 14, wherein each of the first latency and the second latency is a timing difference between a reference signal and the other signals among the control signals.

16. The method of claim 15, wherein the reference signal includes a chip selection signal, and the other signals include command signals and address signals.
